(19) United States
(12) Patent Application Publication
(10) Pub. No.: US 2023/0171971 A1
(43) Pub. Date: Jun. 1, 2023

(54) SEMICONDUCTOR STRUCTURE AND METHOD FOR FABRICATING SEMICONDUCTOR STRUCTURE

(71) Applicants: CHANGXIN MEMORY TECHNOLOGIES, INC., Hefei (CN); Beijing Superstring Academy of Memory Technology, Beijing (CN)

(72) Inventors: Xiaoguang WANG, Hefei (CN); Huihui LI, Hefei (CN); Qiang ZHANG, Hefei (CN); Minmin WU, Hefei (CN); Shan WANG, Hefei (CN)

(21) Appl. No.: 17/853,877

(22) Filed: Jun. 29, 2022

Related U.S. Application Data
(63) Continuation of application No. PCT/CN2022/077795, filed on Feb. 25, 2022.

(30) Foreign Application Priority Data
Nov. 30, 2021 (CN) 202111446952.2

(51) Int. Cl. H01L 27/105

(52) U.S. Cl. CPC H01L 27/1052

(57) ABSTRACT

Embodiments relate to the field of semiconductor manufacturing technology, and more particularly, to a semiconductor structure and a method for fabricating a semiconductor structure. The semiconductor structure includes a substrate including a first array region and a second array region. The first array region is provided with a first memory array comprising a plurality of first memory structures, and the second array region is provided with a second memory array comprising a plurality of second memory structures. Compared with related technologies where different memory structures are stacked on a substrate, in this embodiment, the plurality of first memory structures and the plurality of second memory structures are arranged side by side on the substrate, which is advantageous to simplifying fabrication processes and improving production efficiency.

### CROSS-REFERENCE TO RELATED APPLICATION

This application is a continuation of PCT/CN2022/077795, filed on Feb. 25, 2022, which claims priority to Chinese Patent Application No. 2021114469522 titled “SEMICONDUCTOR STRUCTURE AND METHOD FOR FABRICATING SEMICONDUCTOR STRUCTURE” and filed to the State Intellectual Property Office on Nov. 30, 2021, the entire contents of which are incorporated herein by reference.

### TECHNICAL FIELD

Embodiments of the present disclosure relate to the field of semiconductor technology, and more particularly, to a semiconductor structure and a method for fabricating a semiconductor structure.

### BACKGROUND

A dynamic random access memory (DRAM) includes a transistor structure and a capacitor structure, where transistors in the transistor structure are electrically connected to capacitors in the capacitor structure to read data from the capacitors or write data into the capacitors by means of the transistors. A magnetic random access memory (MRAM) includes a transistor structure and a magnetic tunnel junction (MTJ) interposed between two metal lines. By controlling the transistors in the transistor structure, a resistance value of the MTJ is changed to read/write data.

In related technologies, to meet different usage requirements of semiconductor memories, memory cells in the MRAM and memory cells in the DRAM are integrated for use. However, the two types of memory cells are generally stacked in a direction perpendicular to a substrate, which leads to cumbersome fabrication processes and lower production efficiency.

### SUMMARY

According to some embodiments, a first aspect of the present disclosure provides a semiconductor structure including a substrate, which includes a first array region and a second array region. The first array region is provided with a first memory array comprising a plurality of first memory structures, and the second array region is provided with a second memory array comprising a plurality of second memory structures.

In some disclosed embodiments, each of the plurality of first memory structures includes a first bit-line structure, a first transistor structure, and a capacitor structure. The first bit-line structure is positioned below the first transistor, and the capacitor structure is arranged on the corresponding first transistor structure. Each of the plurality of second memory structures includes a source-line structure, a second bit-line structure, and a second transistor structure. The source-line structure is positioned below the second transistor structure, and the second bit-line structure is positioned above the second transistor structure. The first bit-line structure and the source-line structure are arranged in a same layer.

In some disclosed embodiments, the first bit-line structure includes a plurality of first bit lines extending along a first direction and spaced apart in a second direction. The first transistor structure includes a plurality of first active pillars arranged on the plurality of first bit lines, an extension direction of each of the plurality of first active pillars is perpendicular to a surface of the substrate, and a projection of each of the plurality of first active pillars on the substrate is at least partially overlapped with a projection of each of the plurality of first bit lines on the substrate, where the first direction is perpendicular to the second direction. The source-line structure includes a plurality of source lines extending along the first direction and spaced apart in the second direction, and the second transistor structure includes a plurality of second active pillars arranged on the plurality of source lines, where an extension direction of each of the plurality of second active pillars is perpendicular to the surface of the substrate. A projection of each of the plurality of second active pillars on the substrate is at least partially overlapped with a projection of each of the plurality of source lines on the substrate. The plurality of first active pillars and the plurality of second active pillars are arranged in a same layer.

In some disclosed embodiments, the first transistor structure includes a plurality of first word lines extending along the second direction and spaced apart in the first direction, where each of the plurality of first word lines is arranged by surrounding a middle sidewall of each of the plurality of first active pillars. The second transistor structure includes a plurality of second word lines extending along the second direction and spaced apart in the first direction, where each of the plurality of second word lines is arranged by surrounding a middle sidewall of each of the plurality of second active pillars.

The plurality of first word lines and the plurality of second word lines are arranged in a same layer.

In some disclosed embodiments, each of the plurality of first memory structures also includes a plurality of first contact pads, each of the plurality of first contact pads being arranged on corresponding one of the plurality of first active pillars. Each of the plurality of second memory structure also includes a plurality of second contact pads, each of the plurality of second contact pads being arranged on corresponding one of the plurality of second active pillars. The plurality of first contact pads and the plurality of second contact pads are arranged in a same layer.

In some disclosed embodiments, the capacitor structure includes a lower electrode, an upper electrode, and a capacitor dielectric layer. The capacitor dielectric layer is positioned between the lower electrode and the upper electrode, and the upper electrode and the second bit-line structure are arranged in a same layer.

In some disclosed embodiments, each of the plurality of second memory structures includes a plurality of contact structures and a plurality of magnetic memory structures. The plurality of magnetic memory structures are arranged on a corresponding one of the plurality of second contact pads, and the plurality of magnetic memory structures are electrically connected to a plurality of second bit lines by means of the plurality of contact structures.

In some disclosed embodiments, each of the plurality of magnetic memory structures includes a reference layer, a magnetic tunneling barrier layer, and a free layer. The reference layer is arranged on a corresponding one of the plurality of second contact pads, and the magnetic tunneling barrier layer is positioned between the reference layer and the free layer.

In some disclosed embodiments, the second bit-line structure includes a plurality of second bit lines extending along the second direction and spaced apart in the first direction.

According to some embodiments, a second aspect of the present disclosure provide a method for fabricating a semiconductor structure, including:

providing a substrate including a first array region and a second array region; forming a first memory array comprising a plurality of first memory structures arranged in an array on the first array region; and forming a second memory array comprising a plurality of second memory structures arranged in an array on the second array region. The first memory array and the second memory array are formed synchronously.

In some disclosed embodiments, each of the plurality of first memory structures includes a first bit-line structure, a first transistor structure, and a capacitor structure; and each of the plurality of second memory structures includes a source-line structure, a second bit-line structure, and a second transistor structure. The first bit-line structure and the source-line structure are synchronously formed on the first array region and the second array region. The first bit-line structure is positioned below the first transistor, and the capacitor structure is arranged on the corresponding first transistor. The source-line structure is positioned below the second transistor structure, and the second bit-line structure is positioned above the second transistor structure.

In some disclosed embodiments, the first transistor structure includes a plurality of first active pillars, and the second transistor structure includes a plurality of second active pillars. The plurality of first active pillars and the plurality of second active pillars are formed synchronously, an extension direction of each of the plurality of first active pillars is perpendicular to a surface of the substrate, and a projection of each of the plurality of first active pillars on the substrate is at least partially overlapped with a projection of each of the plurality of first bit lines on the substrate. An extension direction of each of the plurality of second active pillars is perpendicular to the surface of the substrate, and a projection of each of the plurality of second active pillars on the substrate is at least partially overlapped with a projection of each of the plurality of source lines on the substrate.

In some disclosed embodiments, the first transistor structure also includes a plurality of first word lines, and the second transistor structure also includes a plurality of second word lines. The plurality of first word lines and the plurality of second word lines are synchronously formed on the first bit-line structure and the source-line structure. The plurality of first word lines extend along the second direction and are spaced apart in the first direction, and each of the plurality of first word lines is arranged by surrounding a middle sidewall of each of the plurality of first active pillars. The plurality of second word lines extend along the second direction and are spaced apart in the first direction, and each of the plurality of second word lines is arranged by surrounding a middle sidewall of each of the plurality of second active pillars.

In some disclosed embodiments, each of the plurality of first memory structures also includes a plurality of first contact pads arranged on corresponding one of the plurality of first active pillars, and each of the plurality of second memory structures also includes a plurality of second contact pads arranged on corresponding one of the plurality of second active pillars. The plurality of first contact pads and the plurality of second contact pads are synchronously formed on the plurality of first active pillars and the plurality of second active pillars.

In some disclosed embodiments, a dielectric layer is formed on each of the plurality of first contact pads and each of the plurality of second contact pads, where the dielectric layer has a plurality of capacitor holes. A projection of each of the plurality of capacitor holes on the substrate is positioned in the first array region and is at least partially overlapped with a projection of each of the plurality of first contact pads on the substrate.

A plurality of partial capacitor structures are formed in the plurality of capacitor holes.

Part of the dielectric layer is removed to expose each of the plurality of second contact pads.

A plurality of magnetic memory structures and a plurality of contact structures are formed in sequence on each of the plurality of second contact pads.

In some disclosed embodiments, the capacitor structure includes a lower electrode, an upper electrode, and a capacitor dielectric layer. The capacitor dielectric layer is positioned between the lower electrode and the upper electrode, and the second bit-line structure includes a plurality of second bit lines positioned above the plurality of contact structures, where the plurality of second bit lines extend along the second direction and are spaced apart in the first direction. The upper electrode and the second bit-line structure are synchronously formed on the capacitor dielectric layer and each of the plurality of contact structures.

Embodiments of the present disclosure provide a semiconductor structure and a method for fabricating a semiconductor structure. The semiconductor structure includes a substrate including a first array region and a second array region. The first array region is provided with a first memory array comprising a plurality of first memory structures, and the second array region is provided with a second memory array comprising a plurality of second memory structures. Compared with related technologies where different memory structures are stacked on a substrate, in this embodiment, the plurality of first memory structures and the plurality of second memory structures are arranged side by side on the substrate, which is advantageous to simplifying fabrication processes and improving production efficiency.

### BRIEF DESCRIPTION OF THE DRAWINGS

To describe the technical solutions in the embodiments of the present disclosure or the existing technologies more clearly, the accompanying drawings required for describing the embodiments or the existing technologies will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a semiconductor structure according to an embodiment of the present disclosure;

FIG. 2 is a vertical view of a substrate according to an embodiment of the present disclosure;

FIG. 3 is a flowchart showing steps of a method for fabricating a semiconductor structure according to an embodiment of the present disclosure;

FIG. 4 is a schematic structural diagram showing a first bit-line structure and a source-line structure synchronously formed in the method for fabricating a semiconductor structure according to an embodiment of the present disclosure;

FIG. 5 is a schematic structural diagram showing a plurality of first active pillars and a plurality of second active pillars synchronously formed in the method for fabricating a semiconductor structure according to an embodiment of the present disclosure;

FIG. 6 is a schematic structural diagram showing a plurality of first word lines and a plurality of second word lines synchronously formed in the method for fabricating a semiconductor structure according to an embodiment of the present disclosure;

FIG. 7 is a schematic structural diagram showing a plurality of first contact pads and a plurality of second contact pads synchronously formed in the method for fabricating a semiconductor structure according to an embodiment of the present disclosure;

FIG. 8 is a schematic structural diagram showing a dielectric layer formed in the method for fabricating a semiconductor structure according to an embodiment of the present disclosure;

FIG. 9 is a schematic structural diagram showing a plurality of partial capacitor structures formed in the method for fabricating a semiconductor structure according to an embodiment of the present disclosure;

FIG. 10 is a schematic structural diagram obtained after the dielectric layer is removed in the method for fabricating a semiconductor structure according to an embodiment of the present disclosure;

FIG. 11 is a schematic structural diagram showing a plurality of magnetic memory structures formed in the method for fabricating a semiconductor structure according to an embodiment of the present disclosure;

FIG. 12 is a schematic structural diagram showing a plurality of contact structures formed in the method for fabricating a semiconductor structure according to an embodiment of the present disclosure; and

FIG. 13 is a schematic structural diagram showing an upper electrode and a second bit-line structure synchronously formed in a method for fabricating a semiconductor structure according to an embodiment of the present disclosure.

### DETAILED DESCRIPTION

To make the above objectives, features, and advantages of the embodiments of the present disclosure more apparent and lucid, the technical solutions in the embodiments of the present disclosure will be described clearly and completely below with reference to the accompanying drawings in the embodiments of the present disclosure. Apparently, the described embodiments are merely some but not all of the embodiments of the present disclosure. All other embodiments obtained by a person of ordinary skill in the art based on the embodiments of the present disclosure without creative efforts shall fall within the protection scope of the present disclosure.

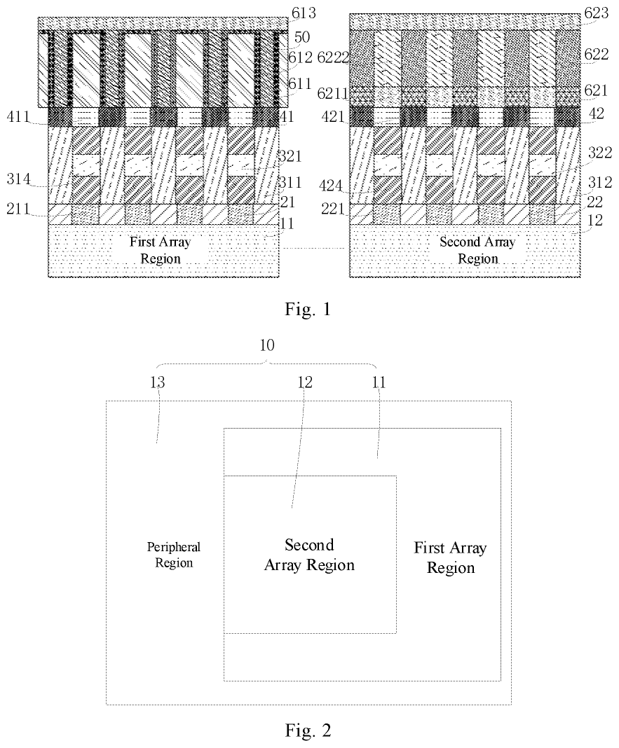

A semiconductor structure provided by an embodiment of the present disclosure includes a substrate. As shown in FIG. 1 and FIG. 2, a material of the substrate 10 may be silicon (Si), germanium (Ge), or silicon germanium (GeSi), silicon carbide (SiC). Furthermore, the material of the substrate 10 may also be silicon on insulator (SOI), germanium on insulator (GOI), or may be other materials, for example, III-V group compounds such as gallium arsenide. The substrate 10 is provided with a peripheral region 13 and an array region adjacent to the peripheral region 13. Referring to FIG. 2, the peripheral region 13 is positioned on a left of the substrate 10 in a position as shown in FIG. 2, the array region is positioned on a right of the substrate 10 in the position as shown in FIG. 2, and the peripheral region 13 may be arranged on a periphery of the array region. Of course, in some other examples, relative locations of the peripheral region 13 and the array region may also be set according to actual needs. The peripheral region 13 may be configured to, for example, form a mating structure mating with the peripheral circuit; and the array region may be configured to, for example, form a mating structure mating with a memory cell. The array region includes a first array region 11 and a second array region 12. With continued reference to FIG. 2, the second array region 12 may be positioned on the left of the array region in the substrate 10, and the first array region 11 may be arranged on the periphery of the second array region 12.

The first array region 11 is provided with a first memory array comprising a plurality of first memory structures, and the second array region 12 is provided with a second memory array comprising a plurality of second memory structures. In this embodiment, a storage principle of each of the plurality of first memory structures in the first memory array is different from that of each of the plurality of second memory structures in the second memory array. For example, each of the plurality of first memory structures may have, for example, memory cells of a dynamic random access memory (DRAM); and each of the plurality of second memory structures may have, for example, memory cells of a magnetic random access memory (MRAM).

It is worth noting that the DRAM is a volatile memory device, and the MRAM is a non-volatile memory device. By respectively arranging each of the plurality of first memory structures with volatile storage characteristics and each of the plurality of second memory structures with non-volatile storage characteristics on the same substrate 10, it is advantageous to further improving flexible storage performance and fast access performance of the semiconductor structure.

An embodiment of the present disclosure provides a semiconductor structure including a substrate 10, where the substrate 10 includes a first array region 11 and a second array region 12. The first array region 11 is provided with a first memory array comprising a plurality of first memory structures; and the second array region 12 is provided with a second memory array comprising a plurality of second memory structures. Compared with related technologies in which different memory structures are stacked on the substrate 10, in this embodiment, each of the plurality of first memory structures and each of the plurality of second memory structures are arranged side by side on the substrate 10, which is advantageous to simplifying technology process, reducing connection complexity, and improving production efficiency.

With continued reference to FIG. 1, in the first array region 11, each of the plurality of first memory structures may include a first bit-line structure 21, a first transistor structure, and a capacitor structure. The first bit-line structure 21 is positioned below the first transistor, and the capacitor structure is arranged on the corresponding first transistor structure. In the second array region 12, each of the plurality of second memory structures may include a source-line structure 22, a second bit-line structure 623, and a second transistor structure. The source-line structure 22 is positioned below the second transistor structure, and the second bit-line structure 623 is positioned above the second transistor structure.

In this embodiment, the first bit-line structure 21 and the source-line structure 22 may be arranged in the same layer, and the first bit-line structure 21 and the source-line structure 22 have an equal height in a direction perpendicular to a surface of the substrate 10 and have a same shape in a cross section parallel to the surface of the substrate 10, such that the first bit-line structure 21 and the source-line structure 22 may be formed synchronously, to simplify fabrication processes of the semiconductor structure.

Referring to FIG. 1, a direction parallel to the substrate 10 is a first direction, and a direction parallel to the substrate 10 and perpendicular to the first direction is a second direction. The first bit-line structure 21 includes a plurality of first bit lines extending along the first direction and spaced apart in the second direction, and the source-line structure 22 includes a plurality of source lines extending along the first direction and spaced apart in the second direction. Materials of the plurality of first bit lines may be the same as those of the plurality of source lines, to further improve fabrication efficiency for the plurality of first bit lines and the plurality of source lines. The materials of the plurality of first bit lines and the plurality of source lines may include a conductive material doped with one or more of polysilicon, titanium, titanium nitride and tungsten.

As shown in FIG. 1, a first isolation structure 211 may be provided between adjacent two of the plurality of first bit lines, and a second isolation structure 221 may be provided between adjacent two of the plurality of source lines. The plurality of first bit lines in the first bit-line structure 21 and the plurality of source lines in the source-line structure 22 may be formed synchronously, so the first isolation structure 211 and the second isolation structure 221 may also be formed synchronously, and the first isolation structure 211 and the second isolation structure 221 may have the same material. Thus, the fabrication processes of the semiconductor structure can be further simplified. The materials of the first isolation structure 211 and the second isolation structure 221 may include, for example, a combination of one or more of silicon nitride, silicon oxynitride, and silicon oxide.

In this embodiment, the first transistor structure includes a plurality of first active pillars 311 arranged on the plurality of first bit lines, and the second transistor structure includes a plurality of second active pillars 312 arranged on the plurality of source lines. The plurality of first active pillars 311 and the plurality of second active pillars 312 have an equal height in the direction perpendicular to the surface of the substrate 10 and have a same shape in the cross section parallel to the surface of the substrate 10, and the plurality of first active pillars 311 and the plurality of second active pillars 312 may be arranged in the same layer, such that the plurality of first active pillars 311 and the plurality of second active pillars 312 may be formed synchronously, to simplify the fabrication processes of the semiconductor structure.

With continued reference to FIG. 1, an extension direction of a given one of the plurality of first active pillars 311 is perpendicular to the surface of the substrate 10, and a projection of the given first active pillar 311 on the substrate 10 is at least partially overlapped with a projection of each of the plurality of first bit lines on the substrate 10, such that the first transistor structure can be electrically connected to the plurality of first bit lines by means of the plurality of first active pillars 311. An extension direction of a given one of the plurality of second active pillars 312 is perpendicular to the surface of the substrate 10, and a projection of the given second active pillar 312 on the substrate 10 is at least partially overlapped with a projection of each of the plurality of source lines on the substrate 10, such that the second transistor structure can be electrically connected to the plurality of source lines by means of the plurality of second active pillars 312. Materials of the plurality of first active pillars 311 may be the same as materials of the plurality of second active pillars 312, and the materials of the plurality of first active pillars 311 and the materials of the plurality of second active pillars 312 may include silicon (Si), germanium (Ge) or silicon germanium (GeSi), silicon carbide (SiC), silicon germanium carbide (SiGeC), indium arsenide (InAs), or other materials such as gallium arsenide and other III-V group compounds. Each of the plurality of first active pillars 311 and each of the plurality of second active pillars 312 have the same structure, including a source region, a drain region, and a channel region positioned between the source region and the drain region. It is worth noting that in this embodiment, each of the plurality of source lines is connected to the source region of each of the plurality of second active pillars 312, and each of the plurality of first bit lines is connected to the source region of each of the plurality of first active pillars 311.

In this embodiment, the first transistor structure also includes a plurality of first word lines 321, and the second transistor structure also includes a plurality of second word lines 322. The plurality of first word lines 321 and the plurality of second word lines 322 may be arranged in the same layer. Each of the plurality of first word lines 321 and each of the plurality of second word lines 322 have the same height in the direction perpendicular to the surface of the substrate 10, and have the same shape in the cross section parallel to the surface of the substrate 10, such that each of the plurality of first word lines 321 and each of the plurality of second word lines 322 can be formed synchronously, to simplify the fabrication processes of the semiconductor structure.

Referring to FIG. 1, the plurality of first word lines 321 extend along the second direction and are spaced apart in the first direction, and each of the plurality of first word lines 321 is arranged by surrounding a middle sidewall of each of the plurality of first active pillars 311. In this embodiment, each of the plurality of first word lines 321 is arranged by surrounding the channel region in the middle of each of the plurality of first active pillars 311, and a first gate dielectric layer may also be arranged between each of the plurality of first word lines 321 and each of the plurality of first active pillars 311. The plurality of second word lines 322 extend along the second direction and are spaced apart in the first direction, and each of the plurality of second word lines 322 is arranged by surrounding a middle sidewall of each of the plurality of second active pillars 312. In this embodiment, each of the plurality of second word lines 322 is arranged by surrounding the channel region in the middle of each of the plurality of second active pillars 312, and a second gate dielectric layer may also be arranged between each of the plurality of second word lines 322 and each of the plurality of second active pillars 312. The second gate dielectric layer and the first gate dielectric layer have the same structure and the same material, and the second gate dielectric layer and the first gate dielectric layer may also be formed synchronously. There is also provided a first insulating structure 314 between each adjacent two of the plurality of first active pillars 311 to isolate the two adjacent first active pillars 311, and there is also provided a second insulating structure 324 between each adjacent two of the plurality of second active pillars 312 to isolate the two adjacent second active pillars 312. The first insulating structure 314 and the second insulating structure 324 have the same structure and the same material, which may include a combination of one or more of silicon nitride, silicon oxynitride, and silicon oxide. The first insulating structure 314 and the second insulating structure 324 may also be formed synchronously.

It should be noted that each of the plurality of first word lines 321 is connected to different first active pillars 311, and each adjacent two of the plurality of first word lines 321 are not connected to each other. Similarly, each of the plurality of second word lines 322 is connected to different second active pillars 312, and each adjacent two of the plurality of second word lines 322 are not connected to each other. Those skilled in the art can adjust a width of each of the plurality of first word lines 321 or each of the plurality of second word lines 322 (the “width” here refers to the width of each of the plurality of first word lines 321 or each of the plurality of second word lines 322 in the first direction), such that each of the plurality of first word lines 321 or each of the plurality of second word lines 322 can connect two adjacent first active pillars 311 or second active pillars 312 as much as possible and as evenly as possible.

It is worth noting that the first transistor structure and the second transistor structure in this embodiment are vertical gate-all-around (GAA) transistors, and this structure has the characteristic of higher integration, which is advantageous to increasing number of first memory structures and second memory structures per unit area to improve arrangement density.

In this embodiment, each of the plurality of first memory structures may also include a plurality of first contact pads 41, each of the plurality of second memory structures may also include a plurality of second contact pads 42, and the plurality of first contact pads 41 and the plurality of second contact pads 42 may be arranged in the same layer. Each of the plurality of first contact pads 41 and each of the plurality of second contact pads 42 have the same height in the direction perpendicular to the surface of the substrate 10, and have the same shape in the cross section parallel to the surface of the substrate 10, such that the plurality of first contact pads 41 and the plurality of second contact pads 42 may be formed synchronously, thereby simplifying the fabrication processes of the semiconductor structure.

With reference to FIG. 1, each of the plurality of first contact pads 41 is arranged on corresponding one of the plurality of first active pillars 311, and each of the plurality of second contact pads 42 is arranged on corresponding one of the plurality of second active pillars 312. The plurality of first contact pads 41 and the plurality of second contact pads 42 may have the same material, which may include a combination of one or more of tungsten (W), tungsten nitride (WN), tungsten silicide (WSi), titanium (Ti), and titanium nitride (TiNₓ). A first insulating block 411 is also provided between any adjacent two of the plurality of first contact pads 41, and a second insulating block 421 is also provided between any adjacent two of the plurality of second contact pads 42. The first insulating block 411 and the second insulating block have the same structure and the same material, which may include a combination of one or more of silicon nitride, silicon oxynitride, and silicon oxide. The first insulating block 411 and the second insulating block 421 may also be formed synchronously.

As shown in FIG. 1, in each of the plurality of first memory structures, a first dielectric layer 50 and a capacitor structure are arranged on the first transistor structure. The first dielectric layer 50 is provided with a plurality of through capacitor holes 51. A projection of each of the plurality of capacitor holes 51 on the substrate 10 is at least partially overlapped with the projection of each of the plurality of first contact pads 41 on the substrate 10, and part of the capacitor structure is arranged in each of the plurality of capacitor holes 51, to connect to each of the plurality of first contact pads 41.

The capacitor structure may include a lower electrode 611, an upper electrode 613, and a capacitor dielectric layer 612 positioned between the lower electrode 611 and the upper electrode 613. The lower electrode 611 covers a hole wall of each of the plurality of capacitor holes 51, the capacitor dielectric layer 612 covers a surface of the lower electrode 611, and the upper electrode 613 covers the capacitor dielectric layer 612. Of course, the capacitor structure may also include other structures in the related technologies, which is not limited in the embodiments of the present disclosure.

As shown in FIG. 1, in each of the plurality of second memory structures, a plurality of contact structures 622, a plurality of magnetic memory structures 621 and a second bit-line structure 623 are arranged on the second transistor, where each of the plurality of magnetic memory structures 621 is arranged on a corresponding one of the plurality of second contact pads 42, and each of the plurality of contact structures 622 is arranged on a corresponding one of the plurality of magnetic memory structures 621. With continued reference to FIG. 1, a projection of each of the plurality of contact structures 622 on the substrate 10 is at least partially overlapped with a projection of each of the plurality of magnetic memory structures 621 on the substrate 10, such that each of the plurality of contact structures 622 is electrically connected to each of the plurality of magnetic memory structures 621. The second bit-line structure 623 is arranged on the plurality of contact structures 622, and each of the plurality of magnetic memory structures 621 is electrically connected to the second bit-line structure 623 by means of each of the plurality of contact structures 622. The second bit-line structure 623 includes a plurality of second bit lines extending along the second direction and spaced apart in the first direction. A first support structure 6211 is also provided between any adjacent two of the plurality of magnetic memory structures 621, and a second support structure 6222 is also provided between any adjacent two of the plurality of contact structures 622.

In this embodiment, the upper electrode 613 and the second bit-line structure 623 may be arranged in the same layer, and the upper electrode 613 and the second bit-line structure 623 have the same height in the direction perpendicular to the surface of the substrate 10, and have the same shape in the cross section parallel to the surface of the substrate 10, such that the upper electrode 613 and the second bit-line structure 623 may be formed synchronously, thereby simplifying the fabrication processes of the semiconductor structure.

As shown in FIG. 1, each of the plurality of magnetic memory structures 621 in this embodiment is a magnetic tunneling junction (MTJ), including a reference layer, a magnetic tunneling barrier layer, and a free layer, where the reference layer is arranged on a corresponding one of the plurality of second contact pads 42, and the magnetic tunneling barrier layer is positioned between the reference layer and the free layer. That is, in this embodiment, each of the plurality of magnetic memory structures 621 is provided with the reference layer, the magnetic tunneling barrier layer and the free layer in sequence in a direction from getting close to the substrate 10 to getting away from the substrate 10. It should be noted that each of the plurality of magnetic memory structures 621 in another embodiment is provided with the free layer, the magnetic tunneling barrier layer and the reference layer in sequence in the direction from getting close to the substrate 10 to getting away from the substrate 10. In a concrete implementation manner, a material of the free layer and a material of the reference layer may include CoFeB, and a material of the magnetic tunneling barrier layer may be magnesium oxide (MgO).

A principle of each of the plurality of magnetic memory structures 621 is briefly described below. Each of the plurality of magnetic memory structures 621 relies on a quantum tunneling effect to allow electrons to pass through the magnetic tunneling barrier layer, where tunneling probability of polarized electrons is related to a relative magnetization direction of the reference layer and the free layer. The magnetization direction of the reference layer remains unchanged. When the magnetization direction of the reference layer is the same as the magnetization direction of the free layer, the tunneling probability of the polarized electrons is higher. At this moment, each of the plurality of magnetic memory structures 621 exhibits a low-resistance state. When the magnetization direction of the reference layer is the opposite to the magnetization direction of the free layer, the tunneling probability of the polarized electrons is lower. At this moment, each of the plurality of magnetic memory structures 621 exhibits a high-resistance state. The low-resistance state and the high-resistance state of each of the plurality of magnetic memory structures 621 are employed to represent logic states “1” and “0”, to achieve storage of data.

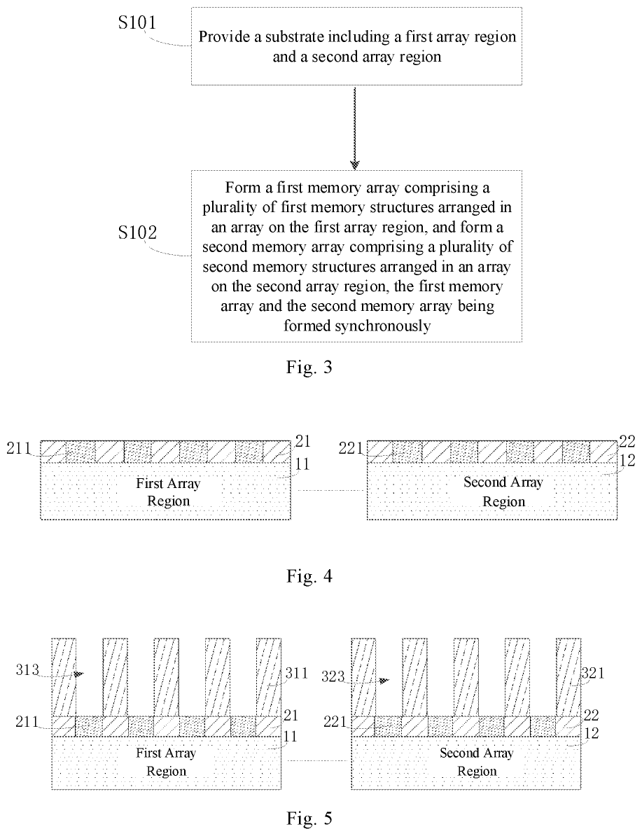

An embodiment of the present disclosure also provides a method for fabricating a semiconductor structure to fabricate the semiconductor structure in the above-mentioned embodiment. Referring to FIG. 3, this method includes:

Step S101: providing a substrate including a first array region and a second array region.

As shown in FIG. 2, the substrate 10 is provided with a peripheral region 13 and an array region adjacent to the peripheral region 13, where the peripheral region 13 is positioned on the left of the substrate 10 in a position as shown in FIG. 2, the array region is positioned on the right of the substrate 10 in the position as shown in FIG. 2, and the peripheral region 13 may be arranged on the periphery of the array region. The array region includes a first array region 11 and a second array region 12. With continued reference to FIG. 2, the first array region 11 is positioned on the left of the array region in the substrate 10, and the second array region 12 is arranged on the periphery of the first array region 11.

In this embodiment, after the substrate 10 is provided, the method also includes:

Step S102: forming a first memory array comprising a plurality of first memory structures arranged in an array on the first array region, and forming a second memory array comprising a plurality of second memory structures arranged in an array on the second array region, the first memory array and the second memory array being formed synchronously.

It should be noted that in this embodiment of the present disclosure, film layer structures in each of the plurality of first memory structures and film layer structures of the same film layer in each of the plurality of second memory structures are formed synchronously. In this way, the first memory array and the second memory array are formed synchronously. In this embodiment, a storage principle of each of the plurality of first memory structures in the first memory array is different from that of each of the plurality of second memory structures in the second memory array. For example, each of the plurality of first memory structures may have, for example, memory cells of a dynamic random access memory (DRAM); and each of the plurality of second memory structures may have, for example, memory cells of a magnetic random access memory (MRAM).

The method for fabricating a semiconductor structure provided by this embodiment includes: providing a substrate 10, which includes a first array region 11 and a second array region 12; forming a first memory array comprising a plurality of first memory structures arranged in an array on the first array region 11, and forming a second memory array comprising a plurality of second memory structures arranged in an array on the second array region 12, the first memory array and the second memory array being formed synchronously. Compared with the related technologies where the plurality of first memory structures and the plurality of second memory structures are separately formed, synchronously forming the plurality of first memory structures and the plurality of second memory structures on the substrate 10 is advantageous to simplifying the fabrication processes and improving the production efficiency.

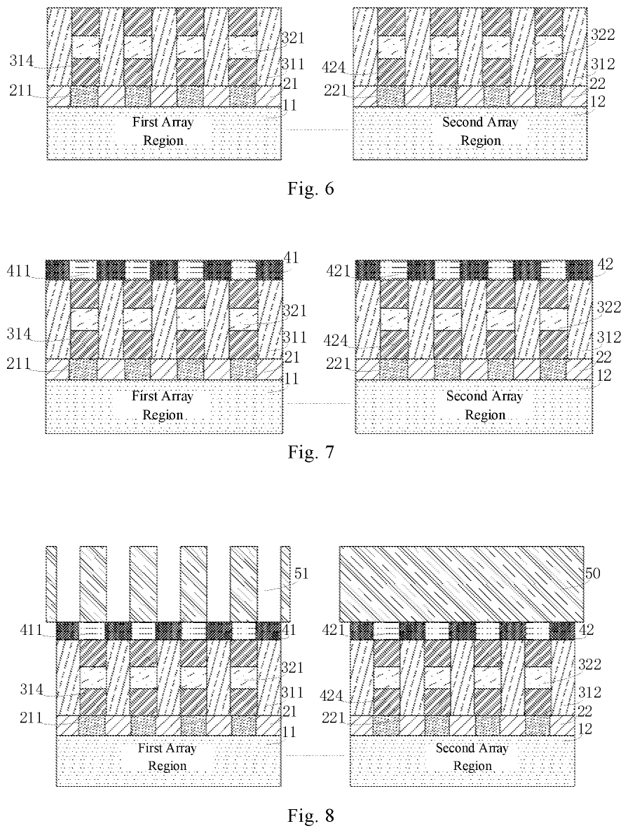

In this embodiment, referring to FIG. 4, FIG. 5 and FIG. 6, each of the plurality of first memory structures includes a first bit-line structure 21, a first transistor structure and a capacitor structure, where the first bit-line structure 21 is positioned below the first transistor, and the capacitor structure is arranged on the corresponding first transistor. Each of the plurality of second memory structures includes a source-line structure 22, a second bit-line structure 623 and a second transistor structure, where the source-line structure 22 is positioned below the second transistor structure, and the second bit-line structure 623 is positioned above the second transistor structure. The synchronously forming the first memory array and the second memory array may include: synchronously forming the first bit-line structure 21 and the source-line structure 22 on the first array region 11 and the second array region 12.

In a concrete implementation manner, the first isolation structure 211 and the second isolation structure 221 may be synchronously formed on the first array region 11 and the second array region 12 of the substrate 10 by means of a deposition process, where the first isolation structure 211 and the second isolation structure 221 are configured to define the first bit-line structure 21 and the source-line structure 22. Next, the first bit-line structure 21 and the source-line structure 22 are synchronously formed between the adjacent first isolation structures 211 and the adjacent second isolation structures 221 by means of the deposition process. A direction parallel to the substrate 10 in the illustrated position is the first direction, and a direction parallel to the substrate 10 and perpendicular to the first direction in the illustrated position is the second direction. The first bit-line structure 21 includes a plurality of first bit lines extending along the first direction and spaced apart in the second direction, and the source-line structure 22 includes a plurality of source lines extending along the first direction and spaced apart in the second direction. Further, to ensure that the first bit-line structure 21 and the source-line structure 22 can be formed synchronously by means of deposition, the first bit-line structure 21 and the source-line structure 22 are made from the same material.

In this embodiment, the first transistor structure may also include a plurality of first active pillars 311, and the second transistor structure may also include a plurality of second active pillars 312. An extension direction of each of the plurality of first active pillars 311 is perpendicular to the surface of the substrate 10, and a projection of each of the plurality of first active pillars 311 on the substrate 10 is at least partially overlapped with a projection of each of the plurality of first bit lines on the substrate 10. An extension direction of each of the plurality of second active pillars 312 is perpendicular to the surface of the substrate 10, and a projection of each of the plurality of second active pillars 312 on the substrate 10 is at least partially overlapped with a projection of each of the plurality of source lines on the substrate 10.

In this embodiment, after the first bit-line structure 21 and the source-line structure 22 are synchronously formed on the first array region 11 and the second array region 12, the plurality of first active pillars 311 and the plurality of second active pillars 312 are synchronously formed on the first bit-line structure 21 and the source-line structure 22.

In a concrete implementation manner, a first initial active pillar and a second initial active pillar may be synchronously formed on the first bit-line structure 21 and the source-line structure 22 by means of a deposition process. To ensure that the first initial active pillar and the second initial active pillar are formed synchronously, the first initial active pillar and the second initial active pillar are made from the same material. After the first initial active pillar and the second initial active pillar are formed, each of the plurality of first active pillars 311 and each of the plurality of second active pillars 312 may be synchronously formed by means of ion implantation for three times. For example, first, a drain region may be respectively formed at the bottom of the first initial active pillar and the second initial active pillar by controlling ion implantation energy and a type of doped ions implanted in the ion implantation technique. Next, a channel region may be respectively formed in the middle of the first initial active pillar and the second initial active pillar by controlling the ion implantation energy and the type of doped ions implanted in the ion implantation technique. Finally, a source region may be respectively formed on the top of the first initial active pillar and the second initial active pillar by controlling the ion implantation energy and the type of doped ions implanted in the ion implantation technique. The type of the doped ions in the drain region may be the same as the type of the doped ions in the source region, for example, the doped ions may include N-type ions. The doped ions in the channel region and the doped ions in the drain region may be of different types, for example, the doped ions may include P-type ions.

In this embodiment, the first transistor structure also includes a plurality of first word lines 321, and the second transistor structure also includes a plurality of second word lines 322. The plurality of first word lines 321 extend along the second direction and are spaced apart in the first direction, and each of the plurality of first word lines 321 is arranged by surrounding a middle sidewall of each of the plurality of first active pillars 311. The plurality of second word lines 322 extend along the second direction and are spaced apart in the first direction, and each of the plurality of second word lines 322 is arranged by surrounding a middle sidewall of each of the plurality of second active pillars 312.

In this embodiment, after each of the plurality of first active pillars 311 and each of the plurality of second active pillars 312 are synchronously formed on the first bit-line structure 21 and the source-line structure 22, each of the plurality of first word lines 321 and each of the plurality of second word lines 322 are formed synchronously on the first bit-line structure 21 and the source-line structure 22.

In a concrete implementation manner, a first filling region 313 is provided between adjacent two of the plurality of first active pillars 311, a second filling region 323 is provided between adjacent two of the plurality of second active pillars 312, and a first insulating material and a second insulating material are synchronously filled into the first filling region 313 and the second filling region 323 until the first insulating material and the second insulating material cover the source region of each of the plurality of first active pillars 311 and the source region of each of the plurality of second active pillars 312. A first conductive layer and a second conductive layer are synchronously formed on the first insulating material and the second insulating material, and the first conductive layer and the second conductive layer cover the channel region of each of the plurality of first active pillars 311 and the channel region of each of the plurality of second active pillars 312. Part of the first conductive layer and part of the second conductive layer are removed to synchronously form each of the plurality of first word lines 321 and each of the plurality of second word lines 322. After each of the plurality of first word lines 321 and each of the plurality of second word lines 322 are formed, the first insulating material and the second insulating material are continued to be filled into the first filling region 313 and the second filling region 323, such that the first insulating material in the first filling region 313 forms the first insulating structure 314, and the second insulating material in the second filling region 323 forms the second insulating structure 324. It should be noted that to form the first insulating structure 314 and the second insulating structure 324 synchronously, the first insulating material and the second insulating material are made from the same material; and to form each of the plurality of first word lines 321 and each of the plurality of second word lines 322 synchronously, the first conductive layer and the second conductive layer are made from the same material.

In this embodiment, referring to FIG. 7, each of the plurality of first memory structures also includes a plurality of first contact pads 41 arranged on corresponding one of the plurality of first active pillars 311, and each of the plurality of second memory structures also includes a plurality of second contact pads 42 arranged on corresponding one of the plurality of second active pillars 312.

In this embodiment, after each of the plurality of first word lines 321 and each of the plurality of second word lines 322 are synchronously formed on the first bit-line structure 21 and the source-line structure 22, the method also includes: synchronously forming each of the plurality of first contact pads 41 and each of the plurality of second contact pads 42 on each of the plurality of first active pillars 311 and each of the plurality of second active pillars 312.

In a concrete implementation manner, each of the plurality of first contact pads 41 and each of the plurality of second contact pads 42 may be synchronously formed on each of the plurality of first active pillars 311 and each of the plurality of second active pillars 312 by means of a deposition process. Further, the first insulating block 411 and the second insulating block 421 may be synchronously formed between adjacent two of the plurality of first contact pads 41 and adjacent two of the plurality of second contact pads 42 respectively by means of a deposition process. Further, to ensure that the plurality of first contact pads 41 and the plurality of second contact pads 42 can be synchronously formed by means of a deposition process, the plurality of first contact pads 41 and the plurality of second contact pads 42 are made from the same material. To ensure that the first insulating block 411 and the second insulating block 421 can be synchronously formed by means of a deposition process, the first insulating block 411 and the second insulating block 421 are made from the same material.

In this embodiment, referring to FIG. 8, after each of the plurality of first contact pads 41 and each of the plurality of second contact pads 42 are synchronously formed on each of the plurality of first active pillars 311 and each of the plurality of second active pillars 312, the method also includes: forming a dielectric layer 50 on each of the plurality of first contact pads 41 and each of the plurality of second contact pads 42, where the dielectric layer 50 has a plurality of capacitor holes 51, a projection of each of the plurality of capacitor holes 51 on the substrate 10 is positioned in the first array region 11 and is at least partially overlapped with the projection of each of the plurality of first contact pads 41 on the substrate 10. By means of the plurality of capacitor holes s 51 of the dielectric layer 50, a plurality of capacitor structures may be defined, and the dielectric layer 50 can also support the plurality of capacitor structures to prevent collapse. The dielectric layer 50 shields the second array region 12 and also can prevent other film structures from being formed on the plurality of second contact pads 42.

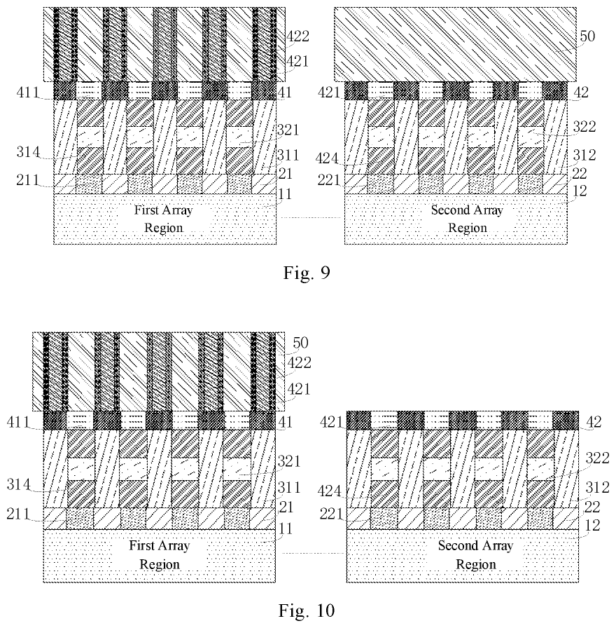

In this embodiment, referring to FIG. 9, after the dielectric layer 50 is formed, the method also includes: forming a plurality of partial capacitor structures in the plurality of capacitor holes 51. Each of the plurality of capacitor structures may include a lower electrode 611, an upper electrode 613, and a capacitor dielectric layer 612 positioned between the lower electrode 611 and the upper electrode 613. As shown in FIG. 9, each of the plurality of partial capacitor structures includes a lower electrode 611 and a capacitor dielectric layer 612, where the lower electrode 611 covers a hole wall of each of the plurality of capacitor holes 51, and the capacitor dielectric layer 612 covers a surface of the lower electrode 611 and fills up each of the plurality of capacitor holes 51. Of course, each of the plurality of capacitor structures may also include other structures in the related technologies, which is not limited in the embodiments of the present disclosure.

In this embodiment, referring to FIG. 10, after the plurality of capacitor structures are formed in the plurality of capacitor holes 51, the method also includes: removing part of the dielectric layer 50 to expose each of the plurality of second contact pads 42, thereby facilitating to subsequently form other film structures on the plurality of second contact pads 42.

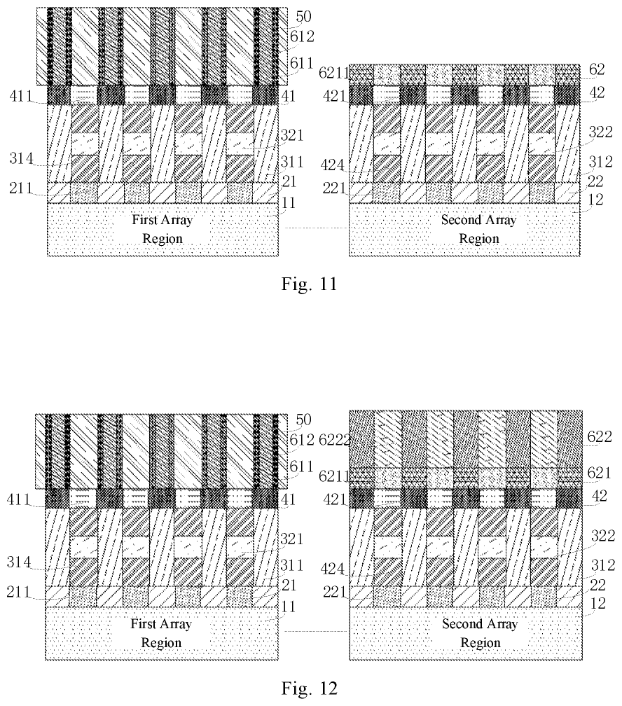

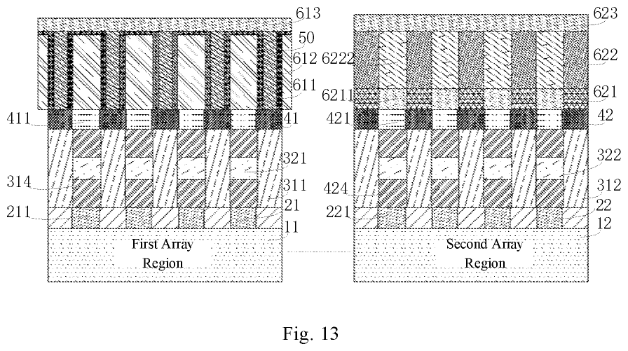

Referring to FIG. 11 and FIG. 12, a plurality of magnetic memory structures 621 and a plurality of contact structures 622 are formed in sequence on the plurality of second contact pads 42. Each of the plurality of magnetic memory structures 621 in this embodiment is a magnetic tunneling junction (MTJ), which includes a reference layer, a magnetic tunneling barrier layer and a free layer, and the concrete structure and working principle thereof are not repeated here. A projection of each of the plurality of contact structures 622 on the substrate 10 is at least partially overlapped with a projection of each of the plurality of magnetic memory structures 621 on the substrate 10, such that each of the plurality of contact structures 622 is electrically connected to each of the plurality of magnetic memory structures 621. In a concrete implementation manner, the plurality of magnetic memory structures 621 and the plurality of contact structures 622 may be formed by means of a deposition process. Referring to FIG. 13, a first support structure 6211 is also arranged between adjacent two of the plurality of magnetic memory structures 621, and a second support structure 6222 is also arranged between adjacent two of the plurality of contact structures 622.

In this embodiment, referring to FIG. 13, after the plurality of magnetic memory structures 621 and the plurality of contact structures 622 are formed in sequence on the plurality of second contact pads 42, the method also includes: synchronously forming the upper electrode 613 and the second bit-line structure 623 on the capacitor dielectric layer 612 and each of the plurality of contact structures 622.

The second bit-line structure 623 includes a plurality of second bit lines positioned above each of the plurality of contact structures 622, where the plurality of second bit lines extend along the second direction and are spaced apart in the first direction. The upper electrode 613 covers the capacitor dielectric layer 612. Further, to ensure that the upper electrode 613 and the second bit-line structure 623 can be synchronously formed by means of deposition, the upper electrode 613 and the second bit-line structure 623 are made from the same material.

Those skilled in the art may clearly understand that for the convenience and brevity of description, division of the above functional modules is merely taken as an example for illustration. In actual applications, the foregoing functions may be allocated to different functional modules and implemented according to needs. That is, an internal structure of an apparatus is divided into different functional modules to implement all or part of the functions described above. For a detailed working process of the apparatus described above, reference may be made to the corresponding process in the foregoing method embodiments, and details are not described herein again.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. A semiconductor structure comprising a substrate, the substrate comprising a first array region and a second array region;
the first array region being provided with a first memory array comprising a plurality of first memory structures, and the second array region being provided with a second memory array comprising a plurality of second memory structures.

2. The semiconductor structure according to claim 1, wherein each of the plurality of first memory structures comprises a first bit-line structure, a first transistor structure and a capacitor structure, the first bit-line structure being positioned below the first transistor, and the capacitor structure being arranged on the corresponding first transistor structure;
each of the plurality of second memory structures comprises a source-line structure, a second bit-line structure and a second transistor structure, the source-line structure being positioned below the second transistor structure, and the second bit-line structure being positioned above the second transistor structure; and
the first bit-line structure and the source-line structure are arranged in a same layer.

3. The semiconductor structure according to claim 2, wherein the first bit-line structure comprises a plurality of first bit lines extending along a first direction and spaced apart in a second direction, the first transistor structure comprising a plurality of first active pillars arranged on the plurality of first bit lines, an extension direction of each of the plurality of first active pillars being perpendicular to a surface of the substrate, a projection of each of the plurality of first active pillars on the substrate being at least partially overlapped with a projection of each of the plurality of first bit lines on the substrate, and the first direction being perpendicular to the second direction;
the source-line structure comprises a plurality of source lines extending along the first direction and spaced apart in the second direction, the second transistor structure comprising a plurality of second active pillars arranged on the plurality of source lines, an extension direction of each of the plurality of second active pillars being perpendicular to the surface of the substrate, and a projection of each of the plurality of second active pillars on the substrate being at least partially overlapped with a projection of each of the plurality of source lines on the substrate; and
the plurality of first active pillars and the plurality of second active pillars are arranged in a same layer.

4. The semiconductor structure according to claim 3, wherein the first transistor structure comprises a plurality of first word lines extending along the second direction and spaced apart in the first direction, each of the plurality of first word lines being arranged by surrounding a middle sidewall of each of the plurality of first active pillars;
the second transistor structure comprises a plurality of second word lines extending along the second direction and spaced apart in the first direction, each of the plurality of second word lines being arranged by surrounding a middle sidewall of each of the plurality of second active pillars; and
the plurality of first word lines and the plurality of second word lines are arranged in a same layer.

5. The semiconductor structure according to claim 4, wherein each of the plurality of first memory structures further comprises a plurality of first contact pads, each of the plurality of first contact pads being arranged on corresponding one of the plurality of first active pillars;
each of the plurality of second memory structure further comprises a plurality of second contact pads, each of the plurality of second contact pads being arranged on corresponding one of the plurality of second active pillars; and
the plurality of first contact pads and the plurality of second contact pads are arranged in a same layer.

6. The semiconductor structure according to claim 2, wherein the capacitor structure comprises a lower electrode, an upper electrode and a capacitor dielectric layer, the capacitor dielectric layer being positioned between the lower electrode and the upper electrode, and the upper electrode and the second bit-line structure being arranged in a same layer.

7. The semiconductor structure according to claim 5, wherein each of the plurality of second memory structures comprises a plurality of contact structures and a plurality of magnetic memory structures, each of the plurality of magnetic memory structures being arranged on a corresponding one of the plurality of second contact pads, and each of the plurality of magnetic memory structures being electrically connected to each of a plurality of second bit lines by means of each of the plurality of contact structures.

8. The semiconductor structure according to claim 7, wherein each of the plurality of magnetic memory structures comprises a reference layer, a magnetic tunneling barrier layer and a free layer, the reference layer being arranged on a corresponding one of the plurality of second contact pads, and the magnetic tunneling barrier layer being positioned between the reference layer and the free layer.

9. The semiconductor structure according to claim 6, wherein the second bit-line structure comprises a plurality of second bit lines extending along the second direction and spaced apart in the first direction.

10. A method for fabricating a semiconductor structure, comprising:
providing a substrate comprising a first array region and a second array region; and
forming a first memory array comprising a plurality of first memory structures arranged in an array on the first array region, and forming a second memory array comprising a plurality of second memory structures arranged in an array on the second array region, the first memory array and the second memory array being formed synchronously.

11. The method for fabricating a semiconductor structure according to claim 10, wherein each of the plurality of first memory structures comprises a first bit-line structure, a first transistor structure and a capacitor structure, each of the plurality of second memory structures comprising a source-line structure, a second bit-line structure, and a second transistor structure;
the first bit-line structure and the source-line structure are synchronously formed on the first array region and the second array region;
the first bit-line structure is positioned below the first transistor, the capacitor structure being arranged on the corresponding first transistor; and
the source-line structure is positioned below the second transistor structure, the second bit-line structure being positioned above the second transistor structure.

12. The method for fabricating a semiconductor structure according to claim 11, wherein the first transistor structure comprises a plurality of first active pillars, the second transistor structure comprising a plurality of second active pillars;
the plurality of first active pillars and the plurality of second active pillars are formed synchronously; and
an extension direction of each of the plurality of first active pillars is perpendicular to a surface of the substrate, a projection of each of the plurality of first active pillars on the substrate being at least partially overlapped with a projection of each of the plurality of first bit lines on the substrate; and an extension direction of each of the plurality of second active pillars being perpendicular to the surface of the substrate, and a projection of each of the plurality of second active pillars on the substrate being at least partially overlapped with a projection of each of the plurality of source lines on the substrate.

13. The method for fabricating a semiconductor structure according to claim 12, wherein the first transistor structure further comprises a plurality of first word lines, the second transistor structure further comprising a plurality of second word lines;
the plurality of first word lines and the plurality of second word lines are synchronously formed on the first bit-line structure and the source-line structure; and
the plurality of first word lines extend along the second direction and are spaced apart in the first direction, each of the plurality of first word lines being arranged by surrounding a middle sidewall of each of the plurality of first active pillars; and the plurality of second word lines extending along the second direction and being spaced apart in the first direction, and each of the plurality of second word lines being arranged by surrounding a middle sidewall of each of the plurality of second active pillars.

14. The method for fabricating a semiconductor structure according to claim 13, wherein each of the plurality of first memory structures further comprises a plurality of first contact pads arranged on corresponding one of the plurality of first active pillars, each of the plurality of second memory structures further comprising a plurality of second contact pads arranged on corresponding one of the plurality of second active pillars; and
the plurality of first contact pads and the plurality of second contact pads are synchronously formed on the plurality of first active pillars and the plurality of second active pillars.

15. The method for fabricating a semiconductor structure according to claim 14, wherein a dielectric layer is formed on each of the plurality of first contact pads and each of the plurality of second contact pads, the dielectric layer having a plurality of capacitor holes, a projection of each of the plurality of capacitor holes on the substrate being positioned in the first array region and being at least partially overlapped with a projection of each of the plurality of first contact pads on the substrate;
a plurality of partial capacitor structures are formed in the plurality of capacitor holes;
part of the dielectric layer is removed to expose each of the plurality of second contact pads; and
a plurality of magnetic memory structures and a plurality of contact structures are formed in sequence on each of the plurality of second contact pads.

16. The method for fabricating a semiconductor structure according to claim 15, wherein
the capacitor structure comprises a lower electrode, an upper electrode and a capacitor dielectric layer, the capacitor dielectric layer being positioned between the lower electrode and the upper electrode, the second bit-line structure comprising a plurality of second bit lines positioned above the plurality of contact structures, and the plurality of second bit lines extending along the second direction and being spaced apart in the first direction; and
the upper electrode and the second bit-line structure are synchronously formed on the capacitor dielectric layer and each of the plurality of contact structures.
